(19) United States
(12) Patent Application Publication
(10) Pub. No.: US 2025/0226309 A1
(43) Pub. Date: Jul. 10, 2025

(54) Delivering electrical power and data signals from the backside of integrated circuit device

(71) Applicant: Marvell Asia Pte Ltd, Singapore (SG)

(72) Inventor: Runzi Chang, Saratoga, CA (US)

(21) Appl. No.: 19/014,263

(22) Filed: Jan. 9, 2025

Related U.S. Application Data
(60) Provisional application No. 63/618,991, filed on Jan. 9, 2024.

(51) Int. Cl. H01L 23/522; H01L 23/528; H10D 84/01; H10D 84/83

(52) U.S. Cl. CPC H01L 23/5226; H01L 23/5227; H01L 23/5286; H10D 84/0149; H10D 84/834

(57) ABSTRACT

An electronic device includes: (a) a substrate having transistors formed in the substrate frontside, (b) nano-vias (NVs) formed in the substrate and configured to electrically couple at least some of the transistors at least to the substrate backside, the NVs include power NVs configured to conduct at least electrical power between the substrate backside and the transistors, and signal NVs configured to conduct data signals at least between the substrate frontside and backside, (c) frontside interconnects formed on the substrate frontside and configured to conduct the data signals between the transistors and the signal NVS, and (d) backside interconnects formed on the substrate backside and configured to conduct (i) the electrical power between the power NVs and the power terminals and (ii) the data signals between the signal NVs and the signal terminals, the power terminals and the signal terminals are disposed between the backside interconnects and a package substrate.

### CROSS-REFERENCE TO RELATED APPLICATIONS

This application claims the benefit of U.S. Provisional Patent Application 63/618,991, filed Jan. 9, 2024, whose disclosure is incorporated herein by reference.

### FIELD OF THE DISCLOSURE

The present invention relates generally to electronic devices, and particularly to electronic devices comprising integrated circuits having a backside power delivery network.

### BACKGROUND

Electronic devices, such as ultra large-scale integrated circuits (ULSI) devices, have field effect transistors (FETs), such as Fin FET and gate all-around (GAA) FETs. Such ULSI devices further comprise electrically conductive interconnects (also referred to herein as power rails) patterned over the front surface of the substrate and stacked on top of one another. The interconnects are required to conduct electrical signals, such as (i) electrical power from an external power source to the FETs and (ii) data signals being exchanged between the FETs and with other components of the electronic device.

The interconnects typically comprise layers of metal traces configured to conduct the electrical signals across horizontal planes of the device, and vias connecting between the layers and configured to conduct the electrical signals along a vertical axis of the device. The scaling of ULSIs devices typically requires the formation of a large number (e.g., typically about twenty levels) of the electrical traces and vias and one or more dielectric layers formed between each pair of the levels of the electrical traces. Conducting the electrical signals through the large number of interconnects formed on the front side of the ULSI device increases the electrical resistance of the ULSI device, and results in increased voltage drop within the ULSI device, signal integrity issues caused for example by inductive interference between signals conducted in adjacent power rails, and increased power consumption by the ULSI device.

Various techniques have been developed to mitigate the problems described above. For example, the formation of buried power rail (BPR) or power vias combined with backside power delivery network (BSPDN) at the backside of the substrate, enable delivery of the (i) electrical power through the backside of the substrate, and (ii) data signals through the frontside of the substrate. But separating electrical signals from both sides can increase the complexity of the packaging and the routing of electrical signal in such ULSI devices.

The description above is presented as a general overview of related art in this field and should not be construed as an admission that any of the information it contains constitutes prior art against the present patent application.

### SUMMARY

An embodiment of the present invention that is described herein provides an electronic device including: (a) a substrate having a plurality of transistors formed in a frontside of the substrate, (b) a plurality of nano-vias (NVs) formed in the substrate, the NVs configured to electrically couple one or more transistors among the plurality of transistors at least to a backside of the substrate, the NVs including one or more power NVs configured to conduct at least electrical power between the backside of the substrate and the transistors, and one or more signal NVs configured to conduct data signals at least between the frontside and the backside of the substrate, (c) frontside interconnects formed on the frontside of the substrate, the frontside interconnects configured to conduct the data signals between the transistors and the signal NVS, and (d) backside interconnects formed on the backside of the substrate, the backside interconnects configured to conduct (i) the electrical power between the power NVs and power terminals and (ii) the data signals between the signal NVs and signal terminals, the power terminals and the signal terminals disposed between the backside interconnects and a package substrate.

In some embodiments, the data signals include first and second data signals, the signal NVs include a first signal NV configured to conduct the first data signal from the backside of the substrate to the frontside of the substrate, and a second signal NV configured to conduct a second data signal from the frontside of the substrate to the backside of the substrate, and one or more given power NVs among the power NVs are (i) disposed between the first and second signal NVs, and (ii) configured to reduce interference in at least one of the first and second data signals.

In other embodiments, at least one of the given power NVs includes a ground NV configured to (i) conduct electrical ground to the backside of the substrate, and (ii) reduce crosstalk between the first and second data signals. In yet other embodiments, the electronic device further includes additional ground NVs, and the first signal NV is surrounded by (i) the ground NV and (ii) one or more of the additional ground NVs configured to reduce interference in the first data signal.

In some embodiments, the backside interconnects include (i) power backside interconnects configured to conduct at least the electrical power between the power NVs and the power terminals, and (ii) signal backside interconnects configured to conduct the data signals between the signal NVs and the signal terminals. In other embodiments, the signal terminals include first and second signal terminals, the and signal backside interconnects include first and second signal backside interconnects configured to conduct the first and second data signals between (i) the first and second signal NVs and (ii) the first and second signal terminals, respectively. At least one of the power backside interconnects includes a ground backside interconnect electrically coupled to the ground NV, the ground backside interconnect being configured to (i) conduct the electrical ground from the ground NV to one of the power terminals, and (ii) reduce crosstalk between the first and second data signals conducted by the first and second signal backside interconnects, respectively.

In some embodiments, at least one of the transistors includes a source-drain (SD) electrode buried inside the substrate between the frontside of the substrate and the backside of the substrate, the electronic device further includes an additional signal NV disposed between the frontside of the substrate and the SD electrode, the additional signal NV configured to conduct data signals between the frontside of the substrate and the SD electrode. In other embodiments, at least one of the transistors includes a source-drain (SD) electrode buried inside the substrate between the frontside and the backside of the substrate, the electronic device further includes an additional power NV disposed between the backside of the substrate and the SD electrode, the additional power NV configured to conduct the electrical power between the backside of the substrate and the SD electrode.

In some embodiments, the electronic device further includes one or more layers (i) buried inside the substrate between the frontside and the backside of the substrate, and (ii) electrically coupled to one or more of the transistors, and the electronic device further includes one or more additional signal NVs disposed between the frontside of the substrate and the one or more layers, the one or more additional signal NVs configured to conduct the data signals between the frontside of the substrate and the one or more layers.

In other embodiments, the electronic device further includes one or more layers (i) buried inside the substrate between the frontside and the backside of the substrate, and (ii) electrically coupled to one or more of the transistors, and the electronic device further includes one or more additional power NVs disposed between the backside of the substrate and the one or more layers, the one or more additional power NVs configured to conduct the electrical power between the backside of the substrate and the one or more layers.

There is additionally provided, in accordance with an embodiment of the present invention, a method for fabricating an electronic device, the method includes (a) forming a plurality of transistors in a frontside of a substrate, (b) forming in the substrate a plurality of nano-vias (NVs) electrically coupling one or more transistors among the plurality of transistors at least to a plane in the substrate, the plane intended to be a backside of the substrate, and forming the NVs includes forming (i) power NVs coupled between the plane and the transistors to conduct at least electrical power between the backside of the substrate and the transistors, and (ii) signal NVs coupled between the plane and the frontside of the substrate to conduct data signals at least between the frontside and the backside of the substrate, (c) forming, on the frontside of the substrate, frontside interconnects electrically coupled to the signal NVs to conduct the data signals between the transistors and the signal NVs, (d) exposing the backside of the substrate and the power NVs and signal NVs, by thinning the substrate to the plane, and (e) forming, on the backside of the substrate, backside interconnects electrically coupled to the power NVs and the signal NVs.

In some embodiments, thinning the substrate includes bonding a carrier to the frontside interconnects and polishing the substrate to obtain a predefined thickness between the plane and the frontside of the substrate.

The present disclosure will be more fully understood from the following detailed description of the embodiments thereof, taken together with the drawings in which:

### BRIEF DESCRIPTION OF THE DRAWINGS

FIG. 1 is a schematic, sectional view of an electronic device, in accordance with an embodiment that is described herein;

FIGS. 2, 3, 4 and 5 are schematic sectional views showing operations of a process flow for fabricating the electronic device of FIG. 1, in accordance with embodiments that are described herein; and

FIG. 6 is a flow chart that schematically illustrates a method for fabricating the electronic device of FIG. 1, in accordance with an embodiment that is described herein.

### DETAILED DESCRIPTION OF EMBODIMENTS

Embodiments of the present disclosure that are described herein provide improved techniques for routing electrical power and data signals in electronic devices, such as ULSI devices used in high-performance computing (HPC) applications (e.g., cloud computing and artificial intelligence) in high-speed data communication systems.

In some embodiments, an electronic device comprises a substrate having a plurality of transistors formed in the frontside surface of the substrate. In the present example, each transistor comprises a gate all-around (GAA) field-effect transistor (FET) having a gate electrode and a plurality of source and drain electrodes implemented in the GAA FET as nanosheets or nanowires traversing the gate electrode.

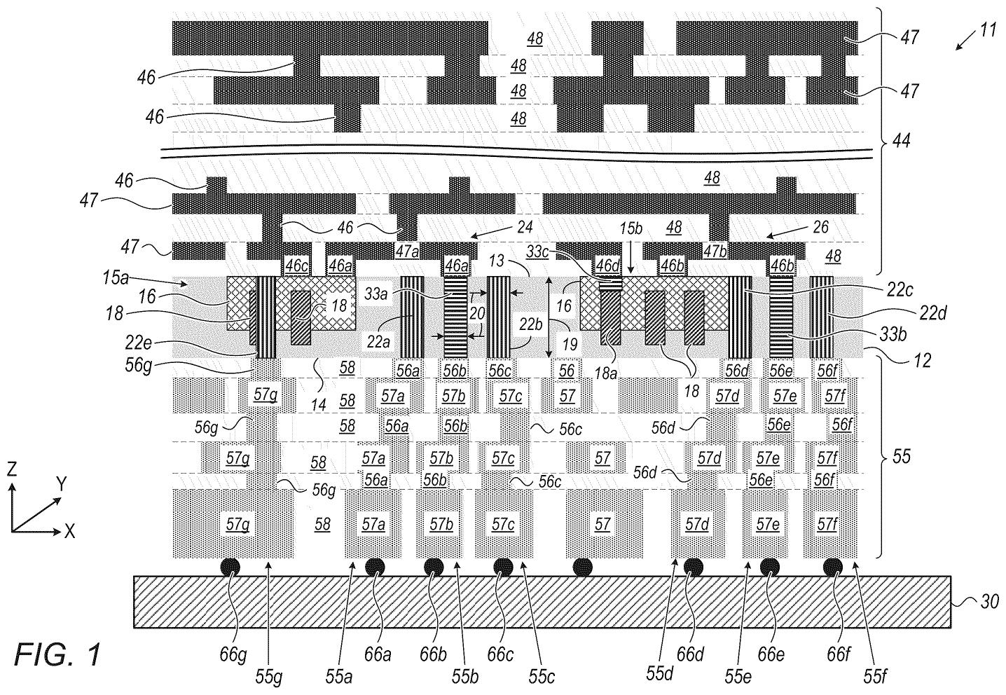

In some embodiments, the electronic device comprises a plurality of nano-vias (NVs) formed in the substrate. The NVs are configured to couple one or more of the transistors to the backside surface of the substrate, and thereby, extend from the backside surface into the substrate. The structure and properties of the NVs are described in detail in FIG. 1 below. The NVs comprise (i) one or more power NVs configured to conduct electrical power from the backside surface of the substrate to the transistors, and (ii) one or more signal NVs configured to conduct data signals between the frontside surface and the backside surface of the substrate.

In some embodiments, the electronic device comprises frontside interconnects formed on the frontside surface of the substrate and configured to conduct the data signals between the transistors and the signal NVs. The electronic device further comprises backside interconnects formed on the backside surface of the substrate and configured to conduct (i) the electrical power between the power NVs and power terminals, and (ii) the data signals between the signal NVs and signal terminals. The power terminals are configured to conduct the electrical power from an external source to the transistors, and the signal terminals are configured to conduct the data signals between the electronic device and other entities, such as a package substrate or an interposer used in the package of the electronic device. The terminals may be implemented in the electronic device using bumps, balls, pads or pins disposed, for example, between the electronic device and the package substrate.

In some embodiments, the data signals comprise first and second data signals, e.g., an input data signal received from the package substrate and an output data signal conducted from the electronic device to the package substrate. In such embodiments, the signal NVs comprise a first signal NV configured to conduct the input data signal from the backside surface to the frontside surface, and a second signal NV configured to conduct an output data signal from the frontside surface to the backside surface of the substrate. Moreover, one or more of the power NVs are formed between the first and second signal NVs. The power NVs are configured to conduct electrical power and electrical ground. As such, the power NVs conducting the ground are (i) also referred to herein as ground NVs and (ii) configured to shield the first and second signal NVs, so as to reduce inductive interference between the input and output data signals.

The disclosed techniques improve the quality (e.g., signal integrity and reduced level of noise) in electrical signals (e.g., electrical power and data signals) routed in the electronic device. Moreover, the disclosed techniques simplify the packaging process, and thereby, reduce the fabrication costs of the aforementioned ULSI devices by enabling the exchanging of all electrical signals (e.g., electrical power and data signals) from the backside of the electronic device.

The description above is presented as a general overview of embodiments of the present disclosure, which are described in detail herein.

FIG. 1 is a schematic, sectional view of an electronic device 11, in accordance with an embodiment that is described herein. Electronic device 11 is also referred to herein as a device 11, for brevity.

In some embodiments, device 11 comprises a semiconductor (e.g., silicon) substrate referred to herein as a substrate 12 having a plurality of transistors, such as transistors 15a and 15b formed in a frontside surface 13 of substrate 12. In the present example, transistors 15a and d 15b comprise gate all-around (GAA) field-effect transistors (FETs) having a gate electrode referred to herein as a gate 16, and a plurality of source and drain (SD) electrodes, referred to herein as SD 18 implemented in transistors 15a and 15b using nanosheets or nanowires traversing gate 16 along the Y-axis of the XYZ coordinate system. In other embodiments, device 11 may comprise any other suitable transistors, such as but not limited to Fin FET or Metal-Oxide semiconductor (MOS) FET transistors.

In some embodiments, electronic device 11 comprises a plurality of nano-vias (NVs) 22 and 33 formed in substrate 12. NVs 22 and 33 are configured to couple one or more of the transistors, e.g., transistors 15a and 15b, to a backside surface 14 of substrate 12. As such, NVs 22 and 33 extend from backside surface 14 into the bulk of substrate 12. In the context of the present disclosure and in the claims, (i) the term frontside refers to frontside surface 13 and additional electrically conductive layers (not shown) and/or tens of nanometers of substrate 12 located adjacent to frontside surface 13 between surfaces 13 and 14, and (ii) the term backside refers to backside surface 14 and additional electrically conductive layers (not shown) and/or tens of nanometers of substrate 12 located adjacent to backside surface 14, between surfaces 13 and 14.

In some embodiments, substrate 12 has a thickness 19 between about 100 nm and 1000 nm along the Z-axis, in the present example a thickness of about 200 nm. In the present example, NVs 22a, 22b, 22c, 22d, 33a and 33b traverse substrate 12 between frontside surface 13 and backside surface 14, so that thickness 19 of substrate 12 equals to the height of NVs 22a-22d and 33a-33b. Moreover, NVs 22 and 33 have a diameter between about 5 nm and 25 nm, in the present example about 20 nm. As such, NVs 22 and 33 have an aspect ratio of about 10 or greater than 10, in the context of the present disclosure and in the claims, the term aspect ratio refers to the height of NVs 22 and 33 (e.g., equals to thickness 19) divided by diameter 20. In some embodiments, a NV 22e is formed between backside surface 14 and SD 18 of transistor 15a to conduct electrical power to transistor 15a, as described in more detail below.

In some embodiments, NVs 22a-22e comprise power NVs configured to conduct electrical power from backside surface 14 of substrate 12 to transistors 15a and 15b. Moreover, NVs 33a and 33b comprise signal NVs configured to conduct data signals between frontside surface 13 and backside surface 14 of substrate 12.

In some embodiments, electronic device 11 comprises frontside interconnects 44 formed on frontside surface 13 substrate of 12. In some embodiments, electronic device 11 comprises one or more electrically conductive layers (not shown) buried in substrate 12 between frontside surface 13 and backside surface 14 as described above. In such embodiments, at least one of frontside interconnects 44 may be extended into substrate 12 and electrically coupled to one or more of the aforementioned electrically conductive layers buried in the frontside of substrate 12 adjacent to frontside surface 13. In some embodiments, a NV 33c is disposed between surface 13 and an SD 18a of transistor 15b. NV 33c is configured to conduct data signals to transistor 15b, as will be described in more detail below.

In the present example, frontside interconnects 44 are implemented in: (i) multiple (e.g., typically between about fifteen and twenty) layers of electrically conductive traces 47 formed in XY planes of the XYZ coordinate system, and (ii) vias 46 formed along the Z-axis of the XYZ coordinate system and configured to electrically couple between traces 47. In some embodiments, traces 47 and vias 46 of frontside interconnects 44 typically are made from copper or from any other suitable electrically conductive material. Moreover, frontside interconnects 44 comprises dielectric layers 48 that are formed between traces 47 and are configured to electrically insulate between different electrical signals conducted by vias 46 and traces 47 patterned in dielectric layers 48. The dashed lines between layers 48 are used to show the multi-layered structure of layers in frontside 48 interconnects 44.

In some embodiments, frontside interconnects 44 are configured to conduct the data signals between transistors 15 and NVs 33. In the present example, a patterned structure 24 of frontside interconnects 44, comprises vias 46a and a trace 47a and configured to conduct input data signals from NV 33a to gate 16 of transistor 15a. Moreover, a patterned structure 26 of frontside interconnects 44, comprises vias 46b and a trace 47b and configured to conduct output data signals from gate 16 of transistor 15a to NV 33b.

In some embodiments, frontside interconnects 44 are configured to conduct data signals, and are not conducting electrical power and/or electrical ground. In the present example, the input data signals are conducted from transistor 15a, through a via 46c and other traces 47 and vias 46 of frontside interconnects 44 and enter transistor 15b through a via 46d coupled with NV 33c. In the present example, via 46c is coupled to gate 16 of transistor 15a, in other embodiments, device 11 may comprise an additional NV 33 (not shown) coupled between via 46c and one of SDs 18 of transistor 15a. In some embodiments, NV 33c is disposed between (i) SD 18a of transistor 15b and (ii) via 46d of frontside interconnects 44 (disposed on surface 13) to electrically couple between transistor 15b and frontside interconnects 44.

In some embodiments, transistor 15b is configured to convert the input signals to the output data signals that are conducted from transistor 15b to NV 33b through patterned structure 26 as described above. It is noted that in typical electronic devices the electrical power is conducted from the power supply to the transistors through power rails implemented in the frontside interconnects. In some embodiments, in the configuration of electronic device 11 frontside interconnects 44 are dedicated to conduct the data signals, so that vias 46 and traces 47 do not conduct electrical power. This configuration reduces the traffic of electrical signals and allows structural optimization (e.g., to obtain reduced capacitance) of vias 46 and traces 47 of frontside interconnects 44 to improve the quality of the data signals conducted by frontside interconnects 44.

In some embodiments, electronic device 11 further comprises (i) backside interconnects 55 formed on backside surface 14 of substrate 12, and (ii) a package substrate 30 described below. Backside interconnects 55 comprise (i) a plurality of dielectric layers 58 made from silicon-oxide or from any other suitable dielectric material, (ii) between about three and six levels of electrical traces 57 patterned in dielectric layers 58 and configured to conduct electrical signals (described below) across XY planes of backside interconnects 55, and (ii) vias 56 connecting between the levels of traces 57 and configured to conduct the electrical signals between the levels of traces 57. The dashed lines between layers 58 are used to show the multi-layered structure of layers 58 in backside interconnects 55.

In some embodiments, vias 56 comprise holes filled with an electrically conductive material (e.g., copper) and traces 57 are made from copper or from any other suitable electrically conductive material. In some embodiments, the deposition of the electrically conductive material (e.g., copper) in vias 56 and traces 57 is carried out in one set of steps. For example, trenches and via holes are etched in dielectric layers 58, one or more seed layers are deposited on the walls of the trenches and via holes, and subsequently, copper electroplating is carried out to fill the via holes and the trenches, and the excess copper is removed from the outer surface of dielectric layer 58 to complete the fabrication of vias 56 and traces 57. It is noted that the process described above may comprise additional sub-operations, such as but not limited to surface preparation and cleaning.

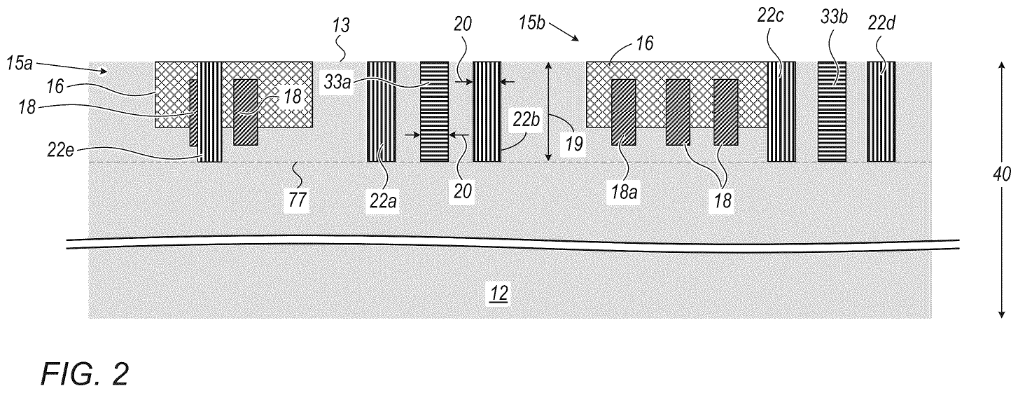

In some embodiments, NVs 22 and 33 have different properties compared to that of vias 46 and 56, in the present example, the differences are based on (i) geometrical parameters described herein, and (ii) fabrication techniques as described in FIG. 2 below. For example, typical diameters of vias 46 are between about 25 nm and 30 nm in the vias 46 connecting to transistors 15a and 15b, and up to about 400 nm in the uppermost vias 46 (i.e., the vias 46 farthest from transistors 15a and 15b). As such, vias 46 have a typical aspect ratio between about 3:1 and 1:1. In some embodiments, typical diameters of vias 56 are about 80 nm (e.g., between about 50 nm and 100 nm) in the vias 56 in close proximity to substrate 12, and up to about 1000 nm in the vias 56 farthest from substrate 12. As such, vias 56 have a typical aspect ratio between about 2:1 and 1:1.

In such embodiments, the diameters of vias 46 and 56 are larger than the typical 20 nm diameter of NVs 22 and 33, and the typical aspect ratios of vias 46 and 56 are less than the aforementioned 10:1 aspect ratio of NVs 22 and 33. It is noted that the diameters are getting smaller in transitions to more advanced technology nodes (e.g., from the 3 nm to the 2 nm node and so forth) and the aspect ratios are getting larger with improvements in the etching and mainly in the film deposition techniques. But in the disclosed techniques, NVs 22 and 33 typically have smaller diameters and higher aspect ratios compared to that of vias 46 and 56, as described in detail above.

In some embodiments, backside interconnects 55 are configured to conduct the data signals between (i) NVs 33a and 33b, and (ii) respective signal terminals 66b and 66e disposed between backside interconnects 55 and package substrate 30. In some embodiments, terminals 66 may be implemented in electronic device 11 using bumps, balls, pads or pins. In the present example, backside interconnect 55b comprises traces 57b and vias 56b stacked over one another that electrically couple between NV 33a and signal terminal 66b. Backside interconnect 55b and signal terminal 66b are configured to conduct the input data signals from package substrate 30 to NV 33a. Moreover, backside interconnect 55e comprises traces 57e and vias 56e stacked over one another and electrically couple between NV 33b and signal terminal 66e. Backside interconnect 55e and signal terminal 66e are configured to conduct the output data signals from package substrate 30 to NV 33b.

In some embodiments, at least one of backside interconnects 55 may be extended into substrate 12 and electrically coupled to one or more of the aforementioned electrically conductive layers buried in the backside of substrate 12 adjacent to backside surface 14.

In some embodiments, one or more of the power NVs, such as NVs 22b and 22c are disposed between the NVs 33a and 33b. In some embodiments, NVs 22b and 22c are configured to reduce crosstalk between the input and output data signals conducted along NVs 33a and 33b, respectively. In the present example, NVs 22a and 22b are disposed at the sides of NV 33a. One or both of NVs 22a and 22b are configured to conduct the electrical ground and are also referred to herein as ground NVs 22. Such ground NVs 22 are configured to shield the input data signal conducted along NV 33a from inductive interferences that may occur in the XZ plane of device 11. Similarly, NVs 22c and 22d that are conducting the electrical ground are configured to shield the output data signal conducted along NV 33b from inductive interferences that may occur in the XZ plane of device 11. Additionally, electronic device 11 may comprise additional NVs 22 (not shown) configured to shield the (i) input data signals conducted along NV 33a and (ii) output data signals conducted along NV 33b, from inductive interferences that may occur in the YZ plane (or in another plane) of device 11. In other words, one or more of NVs 33 may be surrounded by NVs 22 conducting electrical ground (or conducting the electrical power, in some embodiments) and configured to shield the data signals conducted along the respective NVs 33.

In some embodiments, backside interconnects 55a and 55c are configured to conduct the power signals between (i) NVs 22a and 22b, and (ii) power terminals 66a and 66c, respectively. Moreover, backside interconnects 55d and 55f are configured to conduct the power signals between (i) NVs 22c and 22d, and (ii) power terminals 66d and 66f, respectively. In some embodiments, power terminals 66a, 66c, 66d and 66f are configured to conduct the electrical power from package substrate 30 to transistors 15a and 15b.

In the present example, backside interconnect 55a comprises traces 57a and vias 56a stacked over one another and electrically couple between NV 22a and power terminal 66a. Moreover, backside interconnect 55c comprises traces 57c and vias 56c stacked over one another and electrically coupled between NV 22b and power terminal 66c. Similarly, backside interconnects 55d and 55f comprise respective traces 57d and 57f and respective vias 56d and 56f stacked over one another. Backside interconnect 55d is configured to electrically couple between NV 22c and power terminal 66d, and backside interconnect 55f is configured to electrically couple between NV 22d and power terminal 66f.

In some embodiments, one or both of backside interconnects 55a and 55c that are conducting the electrical ground are (i) also referred to herein as ground backside interconnects 55, and (ii) configured to shield the input data signal conducted along backside interconnect 55b. Moreover, one or both of backside interconnects 55d and 55f that are conducting the electrical ground are configured to shield the output data signal conducted along backside interconnect 55e. It is noted that in other embodiments at least one of NVs 22a-22d and at least one of backside interconnects 55a, 55c, 55d and 55f that are assigned to conduct electrical power, may be used to shield the data signals conducted along (i) NVs 33a and backside interconnect 55b, and (ii) NVs 33b and backside interconnect 55e.

In other embodiments, instead of or in addition to package substrate 30, device 11 may comprise an interposer (not shown) or any other suitable substrate that may be used for packaging electronic device 11.

In some embodiments, device 11 comprises an additional backside interconnect 55g comprising traces 57g and vias 56g stacked over one another. In some embodiments, NV 22e is coupled between the uppermost via 56g (along the Z-axis) of backside interconnect 55g and SD 18 of transistor 15a. NV 22e is configured to conduct electrical power from package substrate 30, via a power terminal 66g and backside interconnect 55g, to SD 18 of transistor 15a.

In other embodiments, a portion of backside interconnects 55 may be buried in one or more outer layers disposed between backside surface 13 and substrate 12. For example, the outer surface of the uppermost via 56g (along the Z-axis) of backside interconnect 55g may be buried in substrate 12, e.g., between backside surface 13 and SD 18. In such embodiments, the uppermost via 56g may be directly coupled to SD 18, so that NV 22e is not required in the configuration of device 11.

FIGS. 2-5 are schematic sectional views showing operations of a process flow for fabricating electronic device 11, in accordance with embodiments that are described herein. It is noted that the operations of the process flow comprise fabrication techniques, such as but not limited to film deposition, lithography, etching, planarization, back-grinding and/or polishing and surface cleaning that are known in the art.

Reference is now made to FIG. 2 that illustrates the fabrication of transistors 15 and NVs 22 and 33. Substrate 12 has a thickness 40, e.g., between about 0.6 mm and 1.2 mm, typically about 0.775 mm. In some embodiments, transistors 15a and 15b and NVs 22 and 33, which are described in detail in FIG. 1 above, are fabricated in substrate 12. It is noted that transistors 15a and 15b and NVs 22 and 33 are fabricated from frontside surface 13 into the depth equal to thickness 19, as described in detail in FIG. 1 above.

In some embodiments, NVs 22 and 33 have the smallest diameter that could be fabricated using suitable patterning techniques. For example, the pattern definition of NVs 22 and 33 is carried out using high numerical aperture (High NA) extreme ultraviolet (EUV) lithography (which is the state-of-the-art available technology) followed by etching to obtain a typical diameter between about 5 nm and 25 nm (e.g., about 20 nm). As described above, thickness 19 may be approximately 200 nm, and therefore, the aspect ratio of NVs 22 and 33 is about 10:1 but could be higher than 10:1 (e.g., a 10 nm diameter and 200 nm thickness results in 20:1 aspect ratio). In some embodiments, vias 46 and 56 may be fabricated using (i) EUV lithography (for the vias 46 having diameters between about 25 nm and 50 nm), (ii) immersion-based deep UV (DUV) lithography (also denoted 193i) for the vias 46 and 56 having diameters between about 50 nm and 200 nm, and (iii) DUV (193 nm) lithography and i-line (248 nm) lithography for the vias 46 and 56 having a diameter larger than about 200 nm. It is noted that in vias 56 the relatively larger diameter and smaller aspect ratio are required to obtain reduced resistance, and the aforementioned diameters and aspect ratios of vias 46 are required to obtain reduced capacitance. In other words, the most advanced (and high cost) techniques are used for patterning NVs 22 and 33, and less advanced techniques (and having reduced cost) are used for patterning at least some of vias 46 and 56 and well as traces 47 and 57.

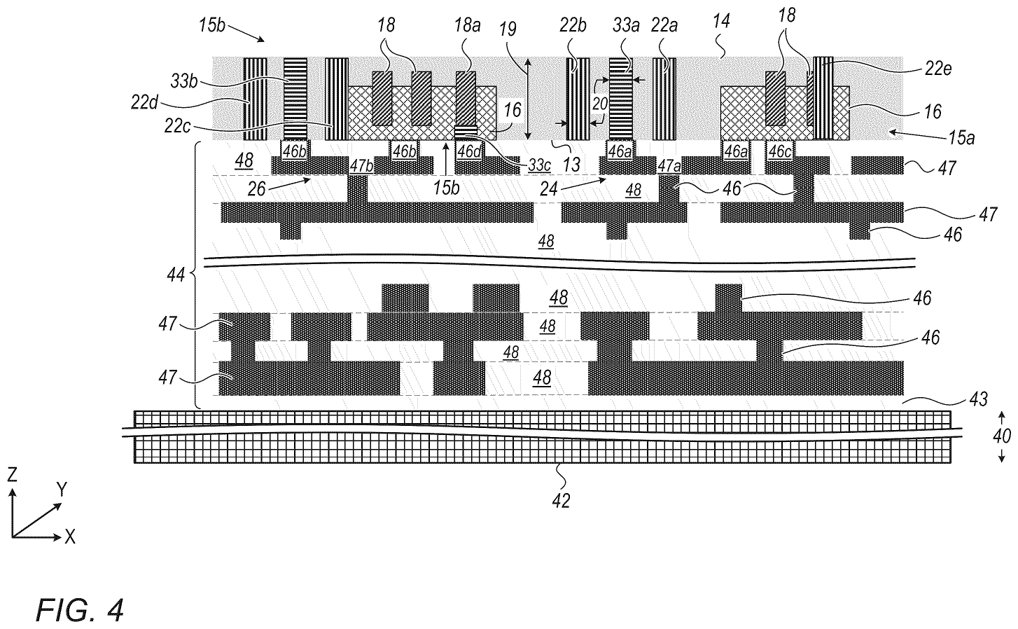

In some embodiments, at the fabrication stage shown in FIG. 2, backside surface 14 is an XY plane 77 situated between the buried edges of vias 22 and 33 in the bulk of substrate 12. It is noted that plane 77 is intended to be backside surface 14 after thinning substrate 12 as will be shown in FIG. 4 below. In other words, plane 77 and backside surface 14 refer to the same planes before and after the thinning of substrate 12, respectively.

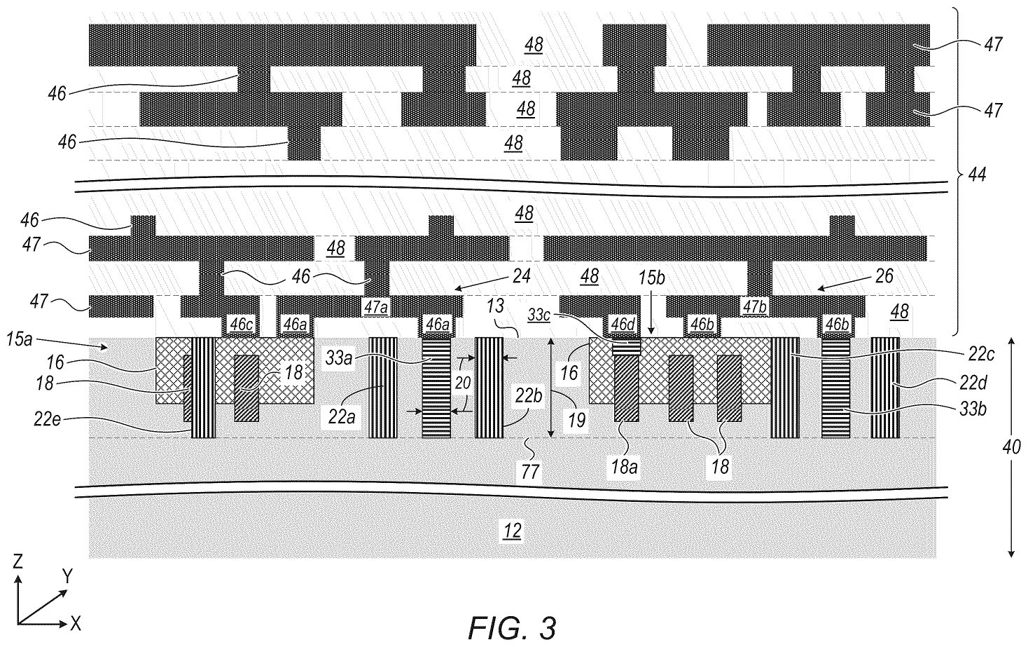

Reference is now made to FIG. 3 that illustrates the fabrication of frontside interconnects 44. In some embodiments, frontside interconnects 44 are fabricated over surface 13, as described in detail in FIG. 1 above. It is noted that substrate 12 still has thickness 40 to endure the mechanical stress associated with the operations for fabricating frontside interconnects 44.

Reference is now made to FIG. 4 that illustrates the thinning of substrate 12. In some embodiments, substrate 12 and frontside interconnects 44 are flipped, and a carrier wafer, referred to herein as a carrier 42, is bonded to a passivation layer 43 formed over frontside interconnects 44. In some embodiments, passivation layer 43 is made from polyimide or any other suitable material configured to protect the outer surface of frontside interconnects 44 from mechanical and thermal stresses and contamination associated with the bonding of carrier 42 and with additional operations described below.

In some embodiments, after the bonding of carrier 42, the thickness of substrate 12 is reduced to the position of plane 77 (shown in FIGS. 2 and 3 above) to obtain thickness 19 (e.g., about 200 nm), so as to expose the outer surface of NVs 22 and 33 that are approximately flush with backside surface 14, as shown and described in FIG. 1 above. It is noted that at the thickness of about 200 nm substrate 12 is brittle and cannot withstand the mechanical and thermal stresses associated with the fabrication process. Therefore, carrier 42 which is typically made from the same material and has similar thickness 40 to that of substrate 12, improves the durability of substrate 12 and frontside interconnects 44 to withstand the mechanical and thermal stresses associated with the fabrication process.

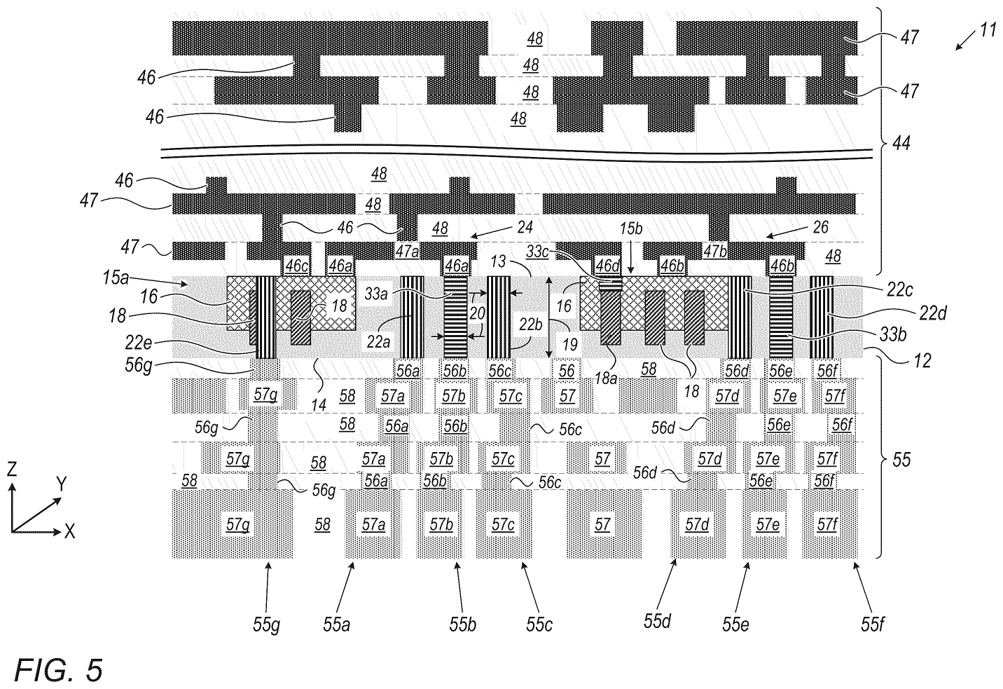

Reference is now made to FIG. 5 that illustrates the fabrication of backside interconnects 55. In some embodiments, backside interconnects 55 are fabricated over backside surface 14 of substrate 12.

In some embodiments, after the formation of backside interconnects 55, the fabrication of electronic device comprises additional operations (not shown in FIG. 5) directed to the singulation and packaging of device 11. The singulation and packaging operations comprise the formation of terminals 66, coupling package substrate 30 with terminals 66, and removal of carrier 42 and passivation layer 43. For example, (i) terminals 66 are formed over the outer surface of traces 57 and 57a-57g, (ii) carrier 42 and passivation layer 43 are removed from frontside interconnects 44, and (iii) a sawing process of substrate 12, frontside interconnects 44 and backside interconnects 55 is carried out. It is noted that the order of these operations may be altered, for example, terminals 66 may be formed after the removal of carrier 42 and passivation layer 43.

In some embodiments, package substrate 30 is coupled (e.g., bonded) to terminals 66 to complete the fabrication process of electronic device 11.

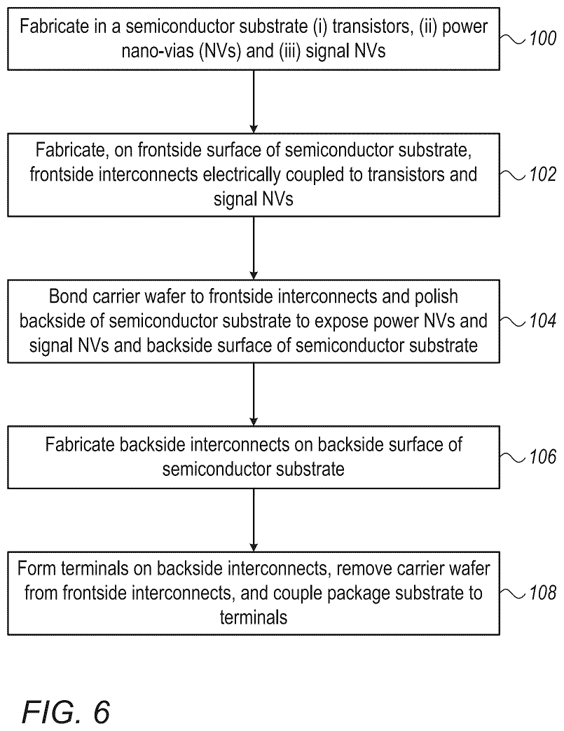

FIG. 6 is a flow chart that schematically illustrates a method for fabricating electronic device 11, in accordance with an embodiment that is described herein.

The method begins at a transistor and nano-via fabrication operation 100 with the fabrication of (i) transistors 15a and 15b, and (ii) NVs 22 and NVs 33, as depicted in FIG. 2 above.

At a frontside interconnects fabrication operation 102, frontside interconnects 44 are fabricated over frontside surface 13 of substrate 12. It is noted that frontside interconnects 44 are electrically coupled to transistors 15a and 15b and to NVs 33 intended to conduct the data signals, as depicted in FIG. 3 above and described in detail in FIG. 1 above.

At a carrier bonding and thinning operation 104, passivation layer 43 is formed over the outer surface of frontside interconnects 44, and carrier 42 is bonded to passivation layer 43. Moreover, as shown in FIG. 4 carrier 42 is flipped and back-grinding and/or polishing processes are carried out to (i) reduce the thickness of substrate 12 to thickness 19 (e.g., about 200 nm), and (ii) expose the outer surface of NVs 22 and 33 that are approximately flush with backside surface 14, as depicted in FIG. 4 above.

At a backside interconnect fabrication operation 106, backside interconnects 55 are fabricated over backside surface 14, as depicted in FIG. 5 above.

At a final assembly operation 108 that concludes the method (i) terminals 66 are formed over the outer surface of backside interconnects 55, (ii) carrier 42 and passivation layer 43 are removed from the outer surface of frontside interconnects 44, (iii) a singulation process of substrate 12, frontside interconnects 44 and backside interconnects 55 is carried out, and (iv) package substrate 30 is bonded to terminals 66, as described in FIG. 5 above. It is noted that a typical process for fabricating electronic device 11 may comprise over one thousand different operations. Thus, the fabrication method described in FIGS. 2-6 is highly simplified for the sake of conceptual clarity.

It is noted that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An electronic device, comprising:
a substrate having a plurality of transistors formed in a frontside of the substrate;
a plurality of nano-vias (NVs) formed in the substrate, the NVs configured to electrically couple one or more transistors among the plurality of transistors at least to a backside of the substrate, the NVs comprising one or more power NVs configured to conduct at least electrical power between the backside of the substrate and the transistors, and one or more signal NVs configured to conduct data signals at least between the frontside and the backside of the substrate;
frontside interconnects formed on the frontside of the substrate, the frontside interconnects configured to conduct the data signals between the transistors and the signal NVs; and
backside interconnects formed on the backside of the substrate, the backside interconnects configured to conduct (i) the electrical power between the power NVs and power terminals and (ii) the data signals between the signal NVs and signal terminals, the power terminals and the signal terminals disposed between the backside interconnects and a package substrate.

2. The electronic device according to claim 1, wherein the data signals comprise first and second data signals, wherein the signal NVs comprise a first signal NV configured to conduct t the first data signal from the backside of the substrate to the frontside of the substrate, and a second signal NV configured to conduct a second data signal from the frontside of the substrate to the backside of the substrate, and wherein one or more given power NVs among the power NVs are (i) disposed between the first and second signal NVs, and (ii) configured to reduce interference in at least one of the first and second data signals.

3. The electronic device according to claim 2, wherein at least one of the given power NVs comprises a ground NV configured to (i) conduct electrical ground to the backside of the substrate, and (ii) reduce crosstalk between the first and second data signals.

4. The electronic device according to claim 3, further comprising additional ground NVs, wherein the first signal NV is surrounded by the ground NV and one or more of the additional ground NVs configured to reduce interference in the first data signal.

5. The electronic device according to claim 3, wherein the backside interconnects comprise (i) power backside interconnects configured to conduct at least the electrical power between the power NVs and the power terminals, and (ii) signal backside interconnects configured to conduct the data signals between the signal NVs and the signal terminals.

6. The electronic device according to claim 5, wherein the signal terminals comprise first and second signal terminals, and the signal backside interconnects comprise first and second signal backside interconnects configured to conduct the first and second data signals between (i) the first and second signal NVs and (ii) the first and second signal terminals, respectively, wherein at least one of the power backside interconnects comprises a ground backside interconnect electrically coupled to the ground NV, the ground backside interconnect being configured to (i) conduct the electrical ground from the ground NV to one of the power terminals, and (ii) reduce crosstalk between the first and second data signals conducted by the first and second signal backside interconnects, respectively.

7. The electronic device according to claim 1, wherein at least one of the transistors comprises a source-drain (SD) electrode buried inside the substrate between the frontside of the substrate and the backside of the substrate, further comprising signal NV disposed between the frontside of the substrate and the SD electrode, the additional signal NV configured to conduct data signals between the frontside of the substrate and the SD electrode.

8. The electronic device according to claim 1, wherein at least one of the transistors comprises a source-drain (SD) electrode buried inside the substrate between the frontside and the backside of the substrate, further comprising an additional power NV disposed between the backside of the substrate and the SD electrode, the additional power NV configured to conduct the electrical power between the backside of the substrate and the SD electrode.

9. The electronic device according to claim 1, further comprising one or more layers (i) buried inside the substrate between the frontside and the backside of the substrate, and (ii) electrically coupled to one or more of the transistors, further comprising one or more additional signal NVs disposed between the frontside of the substrate and the one or more layers, the one or more additional signal NVs configured to conduct the data signals between the frontside of the substrate and the one or more layers.

10. The electronic device according to claim 1, further comprising one or more layers (i) buried inside the substrate between the frontside and the backside of the substrate, and (ii) electrically coupled to one or more of the transistors, further comprising one or more additional power NVs disposed between the backside of the substrate and the one or more layers, the one or more additional power NVs configured to conduct the electrical power between the backside of the substrate and the one or more layers.

11. A method for fabricating an electronic device, the method comprising:
forming a plurality of transistors in a frontside of a substrate;
forming in the substrate a plurality of nano-vias (NVs) electrically coupling one or more transistors among the plurality of transistors at least to a plane in the substrate, the plane intended to be a backside of the substrate, wherein forming the NVs comprises forming (i) power NVs coupled between the plane and the transistors to conduct at least electrical power between the backside of the substrate and the transistors, and (ii) signal NVs coupled between the plane and the frontside of the substrate to conduct data signals at least between the frontside and the backside of the substrate;
forming, on the frontside of the substrate, frontside interconnects electrically coupled to the signal NVs to conduct the data signals between the transistors and the signal NVs;
exposing the backside of the substrate and the power NVs and signal NVs, by thinning the substrate to the plane; and
forming, on the backside of the substrate, backside interconnects electrically coupled to the power NVs and the signal NVs.

12. The method according to claim 11, further comprising coupling power terminals and signal terminals to the backside interconnects to conduct (i) the electrical power between the power NVs and the power terminals, and (ii) the data signals between the signal and the signal terminals.

13. The method according to claim 11, wherein forming the signal NVs comprises forming (i) a first signal NV to conduct a first data signal from the backside to the frontside of the substrate, and (ii) a second signal NV to conduct a second data signal from the frontside to the backside of the substrate, and wherein forming the power NVs comprises forming, between the first and second signal NVs, a given power NV to conduct electrical ground to reduce interference in at least one of the first and second data signals.

14. The method according to claim 13, wherein forming the backside interconnects comprises forming (i) power backside interconnects coupled between the power NVs and the power terminals, and (ii) signal backside interconnects coupled between the signal NVs and the signal terminals.

15. The method according to claim 14, wherein forming the signal terminals comprise forming first and second signal terminals, and forming the signal backside interconnects comprise coupling (i) a first signal backside interconnect between the first signal NV and the first signal terminal, and (ii) a second signal backside interconnect between the second signal NV and the second signal terminal, and wherein forming the power backside interconnects comprises forming, between the first and second signal backside interconnects, a given power backside interconnect coupled between the given power NV and one of the power terminals to conduct the electrical ground to reduce crosstalk between the first and second data signals conducted by the first and second signal backside interconnects, respectively.

16. The method according to claim 11, wherein forming the transistors comprises forming at least one transistor comprising a source-drain (SD) electrode buried inside the substrate between the frontside and the backside of the substrate, further comprising forming an additional signal NV coupled between the frontside of the substrate and the SD electrode to conduct the data signals between the frontside of the substrate and the SD electrode.

17. The method according to claim 11, wherein forming the transistors comprises forming at least one transistor comprising a source-drain (SD) electrode buried inside the substrate between the frontside and the backside of the substrate, further comprising forming an additional power NV coupled between the backside of the substrate and the SD electrode to conduct the power signals between the backside of the substrate and the SD electrode.

18. The method according to claim 11, further comprising forming (a) one or more layers (i) buried inside the substrate between the frontside and the backside, and (ii) electrically coupled to one or more of the transistors, and (b) one or more additional signal NVs coupled between the frontside of the substrate and the one or more layers to conduct the data signals between the frontside of the substrate and the one or more layers.

19. The method according to claim 11, further comprising forming (a) one or more layers (i) buried inside the substrate between the frontside and the backside, and (ii) electrically coupled to one or more of the transistors, and (b) one or more additional power NVs coupled between the backside of the substrate and the one or more layers to conduct the electrical power between the backside of the substrate and the one or more layers.

20. The method according to claim 11, wherein thinning the substrate comprises bonding a carrier to the frontside interconnects and polishing the substrate to obtain a predefined thickness between the plane and the frontside of the substrate.
